(19) United States
(12) Patent Application Publication
(10) Pub. No.: US 2025/0349581 A1
(43) Pub. Date: Nov. 13, 2025

(54) SEMICONDUCTOR PROCESSING APPARATUS

(71) Applicant: TAIWAN SEMICONDUCTOR MANUFACTURING COMPANY, LTD., Hsinchu (TW)

(72) Inventors: Yao-Yuan SHANG, Hsinchu (TW); Chen-Wei LEE, Hsinchu (TW); Ching An CHIH, Hsinchu (TW); Kai Ying LIANG, Hsinchu (TW); Jhih Ting YI, Hsinchu (TW)

(73) Assignee: TAIWAN SEMICONDUCTOR MANUFACTURING COMPANY, LTD., Hsinchu (TW)

(21) Appl. No.: 18/660,641

(22) Filed: May 10, 2024

(51) Int. Cl. H01L 21/67; H01J 37/32; H01L 21/687

(52) U.S. Cl. CPC H01L 21/67259; H01J 37/32642; H01L 21/68785; H01J 2237/24578

(57) ABSTRACT

A semiconductor processing apparatus includes a wafer holder, a top ring surrounding the wafer holder when viewed from top, a lifting mechanism adjacent to the top ring, a monitor module, and a computerized module. The lifting mechanism is configured to lift a part of the top ring. The monitor module is disposed to monitor a current height position of the part of the top ring. The computerized module is electrically connected to the lifting mechanism and the monitor module, and is configured to control the lifting mechanism to lift the part of the top ring from the current height position to a desired height position.

### BACKGROUND

Fabricating semiconductor devices involves a large number of film deposition processes, photolithography processes, etching processes, etc. Some of these processes may utilize plasma. For these processes, uniformity between different pieces or different batches of wafers is crucial for ensuring product quality.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram illustrating a top view of a semiconductor processing apparatus in accordance with some embodiments.

FIG. 2 is a block diagram illustrating connecting relationships among a computerized module, a lifting mechanism, and monitor modules of the semiconductor processing apparatus in accordance with some embodiments.

FIG. 3 is a sectional view taken along line A-A in FIG. 1 in accordance with some embodiments.

FIG. 4 is a sectional view of the semiconductor processing apparatus in accordance with some embodiments.

FIG. 5 is a flow chart illustrating steps of a method for performing a plasma-involving semiconductor process on multiple wafers or multiple batches of wafers in succession in accordance with some embodiments.

FIG. 6 is a schematic diagram illustrating predicted plasma sheath profiles around an edge portion of a wafer to be processed in the semiconductor processing apparatus when a top ring of the semiconductor processing apparatus is in an initial state in accordance with some embodiments.

FIG. 7 is a schematic diagram illustrating predicted plasma sheath profiles around an edge portion of a wafer to be processed in the semiconductor processing apparatus when the top ring has been partly consumed in accordance with some embodiments.

FIG. 8 is a schematic diagram illustrating predicted plasma sheath profiles around an edge portion of a wafer to be processed in the semiconductor processing apparatus when the partly-consumed top ring is lifted in accordance with some embodiments.

FIG. 9 is a flow chart illustrating steps of a method for performing a plasma-involving semiconductor process on multiple wafers or multiple batches of wafers in succession in accordance with some embodiments.

FIG. 10 is a sectional view taken along line A-A in FIG. 1 in accordance with some embodiments.

FIG. 11 is a block diagram illustrating connecting relationships among a computerized module, a lifting mechanism, and monitor modules of the semiconductor processing apparatus in accordance with some embodiments.

FIG. 12 is a sectional view of an edge ring assembly of the semiconductor processing apparatus, illustrating a positional relationship between the lifting mechanism and the edge ring assembly.

FIG. 13 is a schematic diagram illustrating a top view of a semiconductor processing apparatus in accordance with some embodiments.

FIG. 14 is a schematic diagram illustrating a top view of a semiconductor processing apparatus in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

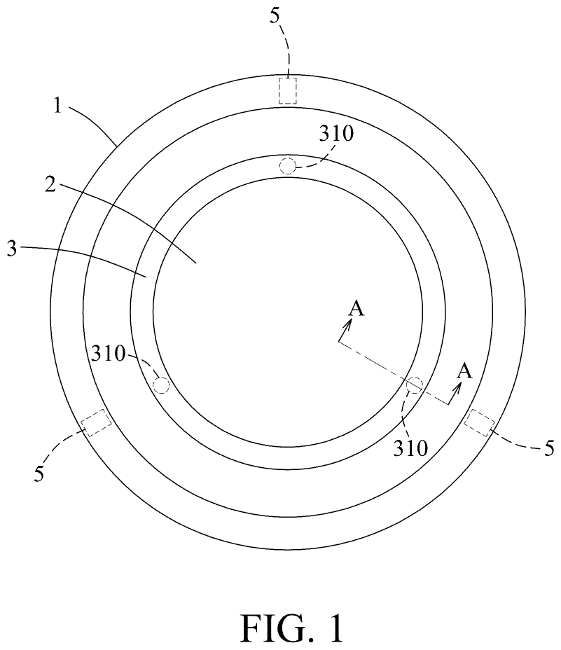

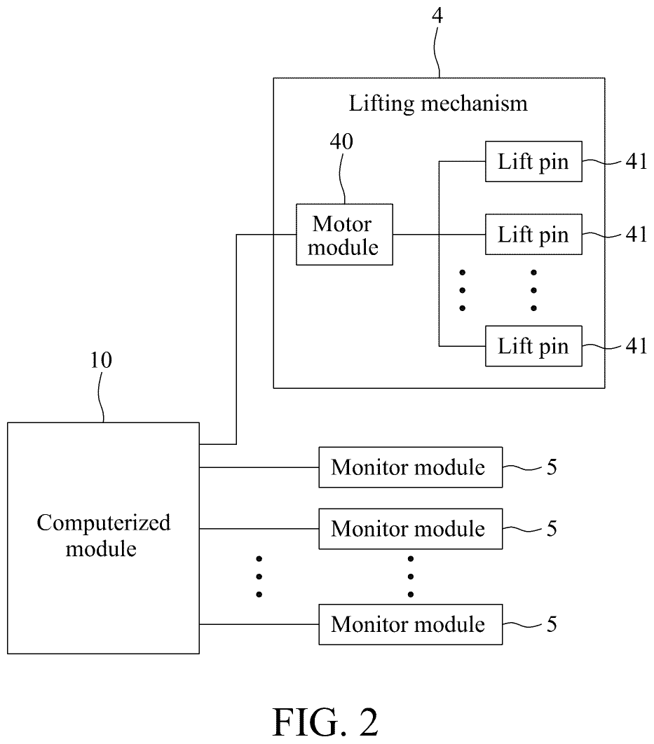

Referring to FIGS. 1 and 2, a semiconductor processing apparatus is illustrated in accordance with a first embodiment. The semiconductor processing apparatus includes a processing chamber defined by a chamber wall 1, a wafer holder 2 disposed in the processing chamber, an edge ring assembly 3 disposed in the processing chamber, a lifting mechanism 4, one or more monitor modules 5, and a computerized module 10.

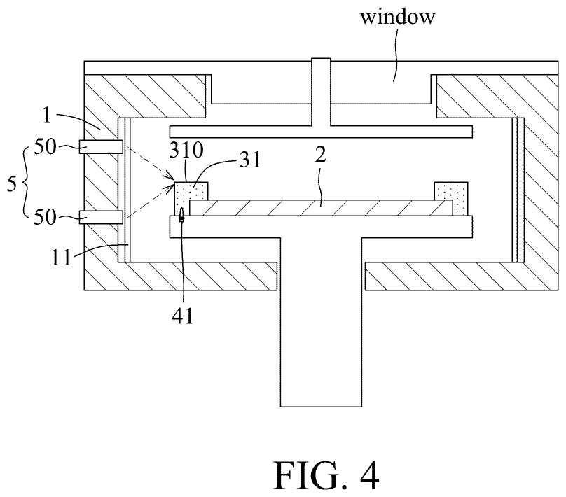

The semiconductor processing apparatus may be, for example, a deposition apparatus or an etching apparatus that is configured to perform a semiconductor process involving use of plasma. Further referring to FIG. 4, the semiconductor processing apparatus includes a plasma generator as depicted by a T-shaped component and an inverted T-shaped component that are respectively disposed under and above the wafer holder 2. In accordance with some embodiments, the plasma generator may include, for example, a gas supply system, electrodes, a radio frequency (RF) power supply, other suitable components, etc., but this disclosure is not limited in this respect.

The wafer holder 2 is configured to hold thereon a wafer to be processed, and may include, for example, an electrostatic chuck (ESC), but this disclosure is not limited in this respect. In some embodiments, one of the electrodes of the plasma generator may be integrated as a part of the wafer holder 2.

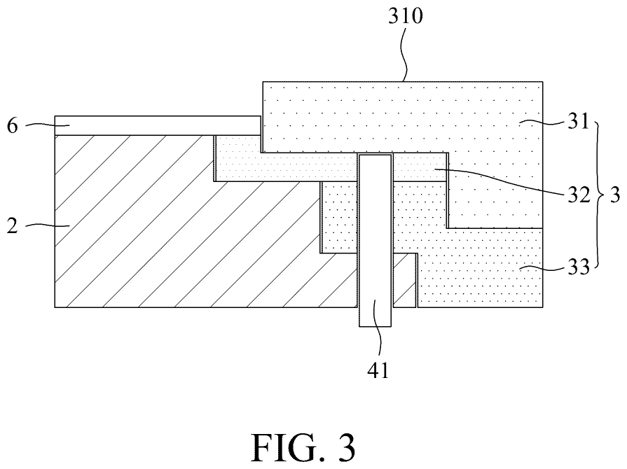

Further referring to FIG. 3, a sectional view taken along line A-A in FIG. 1 is illustrated, with a wafer 6 being placed on the wafer holder 2. The edge ring assembly 3 is adjacent to and surrounds the wafer holder 2, and includes a top ring 31, a middle ring 32 and a bottom ring 33. In the illustrative embodiment, the bottom ring 33 is adjacent to and surrounds a lower portion and a middle portion of the wafer holder 2. The middle ring 32 is stacked over the bottom ring 33, and is adjacent to and surrounds a top portion of the wafer holder 2. The top ring 31 is stacked over the middle ring 32, and surrounds (an upper part of) the top portion of the wafer holder 2 when viewed from top. In the illustrative embodiment, the top ring 31 surrounds but is spaced apart from the top portion of the wafer holder 2 by the middle ring 32 in the sectional view, and has a top surface that is higher than not only a top surface of the wafer holder 2 but also the wafer 6 that is placed on the wafer holder 2. The wafer holder 2 has a stepped structure in the illustrative embodiment, where the lower portion is wider than the middle portion, and the middle portion is wider than the top portion, but this disclosure is not limited in this respect, and the wafer holder 2 may have different structures in other embodiments. The bottom ring 33 has a lower segment, and an upper segment that is disposed over and connected to the lower segment. The lower segment of the bottom ring 33 is adjacent to and surrounds the lower portion of the wafer holder 2. The upper segment of the bottom ring 33 is adjacent to and surrounds the middle portion of the wafer holder 2. The middle ring 32 is L-shaped in the sectional view, and is stacked over the upper segment of the bottom ring 33. The middle ring 32 includes a first segment, and a second segment that extends upward from an inner end of the first segment. The first segment of the middle ring 32 extends horizontally from an upper side of the upper segment of the bottom ring 33 to an upper side of the middle portion of the wafer holder 2. The second segment of the middle ring 32 is adjacent to and surrounds the top portion of the wafer holder 2. In the illustrative embodiment, a top surface of the second segment of the middle ring 32 is coplanar with a top surface of the top portion of the wafer holder 2; when the wafer 6 is placed on the wafer holder 2, an outmost portion of the wafer 6 is disposed over the second segment of the middle ring 32, but this disclosure is not limited in this respect. The top ring 31 is L-shaped in the sectional view and is stacked over the middle ring 32. The top ring 31 includes a first segment that extends vertically, and a second segment that extends horizontally and inwardly from an upper end of the first segment. The first segment of the top ring 31 is disposed at an outer side of the upper segment of the bottom ring 33 and an outer side of the middle ring 32, and is disposed over the lower segment of the bottom ring 33. The second segment of the top ring 31 is adjacent to and surrounds the second segment of the middle ring 32, and extends over the first segment of the middle ring 32. It is noted that this disclosure is not limited to the abovementioned illustrative configurations of the wafer holder 2 and the edge ring assembly 3. In accordance with some embodiments, the wafer holder 2 may include different numbers of portions with different widths. In accordance with some embodiments, it may be that the wafer holder 2 does not include multiple portions that have different widths. In accordance with some embodiments, the middle ring 32 and the bottom ring 33 may be integrated into a base ring. In accordance with some embodiments, the edge ring assembly 3 may include only one ring element that surrounds the top portion of the wafer holder 2, such as the top ring 31. In accordance with some embodiments, the top ring 31 may be made of a dielectric material, such as quartz, a high-k dielectric material, other insulators, or any combination thereof.

Referring to FIGS. 1 through 3, the lifting mechanism 4 is disposed adjacent to the top ring 31, and is operable to lift the top ring 31 from one or multiple parts 310 of the top ring 31. In accordance with the first embodiment, the lifting mechanism 4 includes a motor module 40 electrically connected to the computerized module 10, and at least three lift pins 41. The lift pins 41 are respectively disposed under different parts 310 of the second segment of the top ring 31, extend through the upper segment of the bottom ring 33 and the first segment of the middle ring 32, and are adjacent to a bottom surface of the second segment of the top ring 31. The motor module 40 is connected to one or more lift pins 41, and is controlled by the computerized module 10 to move the lift pin(s) 41 vertically (i.e., selectively in an upward direction or a downward direction). In the illustrative embodiment, the lifting mechanism 4 includes three lift pins 41, all of which are connected to the motor module 40, so the computerized module 10 is able to control each of the lift pins 41 to move individually, but this disclosure is not limited in this respect. In other embodiments, one or more of the lift pins 41 are not connected to the motor module 40, and hence are not movable. In one example, the computerized module 10 may include a computer device that is installed with a software program for controlling the semiconductor processing apparatus, and include one or more processors configured to, when executing instructions of the software program, a variety of actions as described in this specification, but this disclosure is not limited in this respect.

Referring to FIGS. 1 and 2, a number of the monitor module(s) 5 corresponds to a number of those of the part(s) 310 of the top ring 31 under which the “movable” lift pin(s) 41 are (is) disposed. In the illustrative embodiment, the semiconductor processing apparatus includes three monitor modules 5 that respectively correspond to the parts 310 of the top ring 31 because all of the lift pins 41 that are disposed under the parts 310 are movable. In some embodiment where only some of the lift pins 41 are movable, the number of the monitor module(s) 5 may be less than the number of the lift pins 41. In the illustrative embodiment, each of the monitor modules 5 is mounted to or embedded in the chamber wall 1 at a location corresponding in position to the respective one of the parts 310 of the top ring 31, so as to monitor a state of the respective part 310 of the top ring 31, thereby enabling the computerized module 10 to control the lifting mechanism 4 to move the respective part 310 of the top ring 31 based on the state thus detected. The state to be monitored by each of the monitor modules 51 may include, for example, a height position, a thickness, other suitable parameters of the respective part 310 of the top ring 31, or any combination thereof.

Further referring to FIG. 4, each of the monitor modules 5 includes at least two monitor devices 50 that are embedded in the chamber wall 1 at different height positions. Each of the monitor devices 50 of the monitor module 5 is configured to detect a respective distance from a common detection point on a top surface of the corresponding part 310 of the top ring 31 (e.g., a point on a periphery of the corresponding part 310 of the top ring 31). In accordance with some embodiments, each of the monitor devices 50 may include, for example, a laser emitter, a laser detector, a camera recorder, other suitable components, or any combination thereof. In the illustrative embodiment, for each monitor module 5, the chamber wall 1 is formed with multiple through holes at different heights for the monitor devices 50 of the monitor module 5 to be disposed therein, respectively, and the through holes correspond in position to the corresponding part 310 of the top ring 31 and are spaced from the corresponding part 310 of the top ring 31 in a radial direction of the wafer holder 2. A transparent plate 11 is disposed at an inner side of the chamber wall 1 (e.g., attached to an inner surface of the chamber wall 1) to isolate the monitor devices 50 from the processing chamber, so as to protect the monitor devices 50 from being damaged by the plasma during the semiconductor process. In accordance with some embodiments, the transparent plate 11 may be omitted. In the illustrative embodiment, one of the monitor devices 50 is disposed at a position higher than the top surface of the corresponding part 310 of the top ring 31, and the other monitor device 50 is disposed at a position lower than the top surface of the corresponding part 310 of the top ring 31, but this disclosure is not limited in this respect. The computerized module 10 is electrically connected to the monitor devices 50 to receive, from each of the monitor devices 50, the detected distance between the monitor device 50 and the common detection point on the top surface of the corresponding part 310 of the top ring 31, and calculates a height position of the common detection point based on the distances detected by the monitor devices 50 using, for example, trigonometric functions. In one example, the calculated height position of the common detection point may serve as the height position of the corresponding part 310 of the top ring 31.

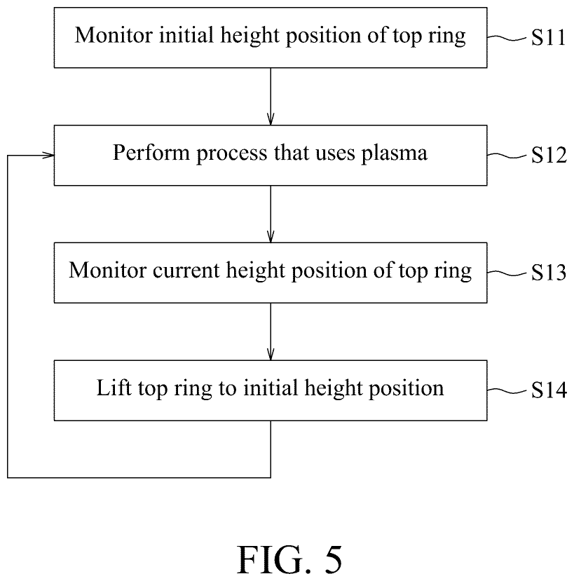

FIG. 5 illustrates a first embodiment of a method for performing a plasma-involving semiconductor process (namely, a semiconductor process that uses plasma) on multiple wafers or multiple batches of wafers in succession, with a consistent plasma sheath profile for different wafers or different batches of wafers, where the plasma-involving semiconductor process is performed in the semiconductor processing apparatus. The method achieves the consistent plasma sheath profile by adjusting heights of the parts 310 of the top ring 31 of the semiconductor processing apparatus (see FIGS. 1, 3 and 4). It is noted that the following description focuses on height adjustment of one of the parts 310 of the top ring 31 for the sake of brevity, and the same or similar method may be applied to other parts 310 of the top ring 31.

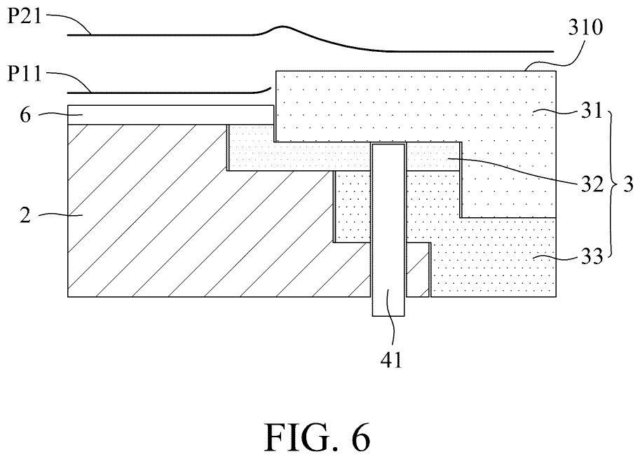

Referring to FIGS. 1, 3 and 5, in step S11, the monitor module 5 monitors an initial height position of the corresponding part 310 of the top ring 31 when the top ring 31 is about to the plasma-involving semiconductor process. In some embodiments, the term “initial” herein is used to describe a condition when the top ring 31 is brand new, and has not undergone any semiconductor process. In some embodiments, the term “initial” herein is used to describe a condition when the top ring 31 may have undergone other semiconductor processes that do not involve the use of plasma, but has not undergone any semiconductor process that uses plasma. In some embodiments, the term “initial” herein is used to describe a time that is “immediately before the upcoming plasma-involving semiconductor process is performed on the first one of wafers to be processed in succession,” regardless of whether or not the top ring 31 has undergone other semiconductor processes that uses plasma. In one example, the computerized module 10 treats the initial height position as a desired height position of the corresponding part 310 of the top ring 31 for use in subsequent steps. FIG. 6 illustrates a first exemplary condition where the top ring 31 has not undergone the plasma-involving semiconductor process and the part 310 of the top ring 31 is not lifted up. A curved line P11 denotes a plasma sheath profile if the plasma-involving semiconductor process is performed under the first exemplary condition and when the top ring 31 is made of an ordinary insulator material, such as quartz, which causes the plasma sheath to be hardly formed over the top ring 31. A curved line P21 denotes a plasma sheath profile if the plasma-involving semiconductor process is performed under the first exemplary condition and when the top ring 31 is made of a high-k material, which causes the plasma sheath to extend and gradually diminish above the top ring 31. In this embodiment, the plasma sheath profile denoted by the curved line P11 or the curved line P12 is a desired plasma sheath profile.

In step S12, the semiconductor processing apparatus performs the plasma-involving semiconductor process on one or more wafers (e.g., a batch of wafers) in succession according to a process recipe, with the part 310 of the top ring 31 being in a height condition that was attained in an immediately previous step (e.g., step S11 or step S14, which will be described later).

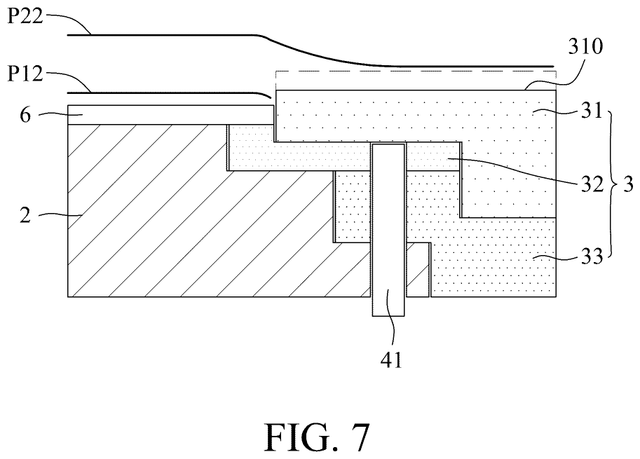

In step S13 that follows step S12, after one or more wafers have undergone the plasma-involving semiconductor process, the monitor module 5 monitors a current height position of the corresponding part 310 of the top ring 31. Since the plasma applied in the semiconductor process may consume the top ring 31 and reduce the top ring 31 in thickness, the monitored current height position may be lower than the desired height position (i.e., the initial height position in this embodiment) for the corresponding part 310 of the top ring 31. FIG. 7 illustrates a second exemplary condition where the top ring 31 has undergone the plasma-involving semiconductor process in step S12 and thus has a reduced thickness, and where the part 310 has not yet been lifted up. A curved line P12 denotes a plasma sheath profile if the next wafer undergoes the plasma-involving semiconductor process under the second exemplary condition and when the top ring 31 is made of an ordinary insulator material, such as quartz. A curved line P22 denotes a plasma sheath profile if the next wafer undergoes the plasma-involving semiconductor process under the second exemplary condition and when the top ring 31 is made of a high-k material. It can be seen from FIGS. 6 and 7 that the lowered top surface of the part 310 of the top ring 31 may result in a different plasma sheath profile, which may lead to inconsistency in terms of device performance between different wafers or different batches of wafers.

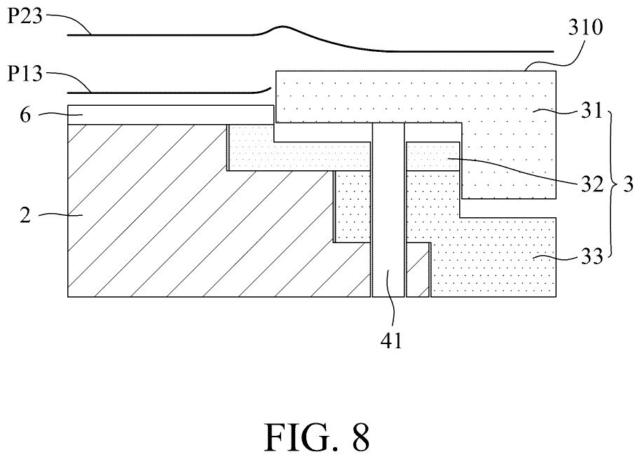

In order to alleviate the inconsistency between different wafers or different batches of wafers, the flow goes to step S14, where the computerized module 10 controls the lifting mechanism 4 to move the part 310 of the top ring 31 from the current height position to the desired height position. In one example, the computerized module 10 subtracts the current height position from the desired height position to obtain a compensatory distance, which corresponds to a reduced thickness of the part 310 of the top ring 31, and controls the motor module 40 (see FIG. 2) to drive the corresponding lift pin 41 that is under the part 310 of the top ring 31 to move upward by the compensatory distance, so as to move the part 310 of the top ring 31 from the current height position to the desired height position, thereby compensating for the reduced thickness of the part 310 of the top ring 31. FIG. 8 illustrates a third exemplary condition where the part 310 of the top ring 31 with the reduced thickness has been lifted to the desired height position, so the top surface of the part 310 of the top ring 31 is at the same place as in the first exemplary condition (see FIG. 6). A curved line P13 denotes a plasma sheath profile if the next wafer undergoes the plasma-involving semiconductor process under the third exemplary condition and when the top ring 31 is made of an ordinary insulator material, such as quartz. A curved line P23 denotes a plasma sheath profile if the next wafer undergoes the plasma-involving semiconductor process under the third exemplary condition and when the top ring 31 is made of a high-k material. It can be seen from FIGS. 6 and 8 that, by lifting the part 310 of the top ring 31 to the desired height position, the plasma sheath profile can be adjusted to be the same as or similar to the previous plasma sheath profile as shown in FIG. 6, thereby minimizing inconsistency between different wafers or different batches of wafers. Then, the flow goes back to step S12 to perform the plasma-involving semiconductor process on the next wafer or next batches of wafers.

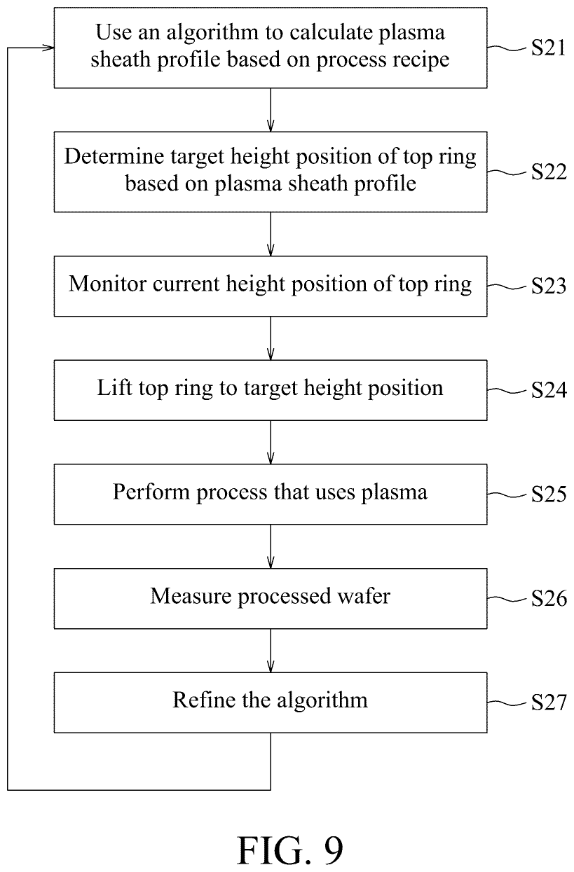

FIG. 9 illustrates a second embodiment of the method for performing a plasma-involving semiconductor process on multiple wafers or multiple batches of wafers in succession, with a consistent plasma sheath profile for different wafers or different batches of wafers. Similarly, for the sake of brevity, the following description focuses on height adjustment of one of the parts 310 of the top ring 31 (see FIGS. 1, 3 and 4), and the same or similar method may be applied to other parts 310 of the top ring 31.

In this embodiment, the computerized module 10 receives a process recipe of the plasma-involving semiconductor process. The process recipe may include plasma-related parameters, such as direct current (DC) power, alternating current (AC) power, bias power, RF pulse duration, RF pulse frequency, gas flow rate by time, processing hours, other suitable parameters, or any combination thereof. The computerized module 10 uses an algorithm to calculate a desired plasma sheath profile based on the process recipe (step S21), and determines a target height position of the part 310 of the top ring 31 based on the desired plasma sheath profile (step S22). In one example, the algorithm may involve the Child-Langmuir law. In one example, the algorithm may involve a neural network that has been trained using a large amount of experimental data and/or previous processing data. In one example, the algorithm may involve big data mining from the large amount of experimental data and/or previous processing data. In one example, the algorithm takes into consideration the goal of achieving good uniformity of plasma sheath in between the edge and the center of a wafer to be processed, so as to obtain the desired plasma sheath profile that is uniform across the wafer to be processed. Then, the computerized module 10 determines, based on the algorithm, the experimental data, and/or the previous processing data, a height position at which the part 310 of the top ring 31 can induce formation of the desired plasma sheath profile, thereby obtaining the target height position that serves as the desired height position for the part 310 of the top ring 31 in this embodiment.

In step S23, the corresponding monitor module 5 monitors a current height position of the part 310 of the top ring 31. When the current height position of the part 310 of the top ring 31 is lower than the desired height position, the computerized module 10 controls the lifting mechanism 4 to lift the part 310 of the top ring 31 from the current height position to the desired height position (step S24). In step S25, the semiconductor processing apparatus performs the plasma-involving semiconductor process on one or more wafers (e.g., a batch of wafers) according to the process recipe, with the part 310 of the top ring 31 being in a height condition that was attained in step S24.

After the plasma-involving semiconductor process is completed, in step S26, the wafer or wafers that have been processed are measured (e.g., measuring critical dimensions of patterns that were formed on the wafer(s) during the plasma-involving semiconductor process), and the measurement data is provided to the computerized module 10 for analysis (i.e., by comparing the measurement data with design values, calculating uniformity across the wafer(s), etc.). Then, in step S27, the computerized module 10 refines the algorithm based on the analysis, and the next cycle of the plasma-involving semiconductor process may be performed using the refined algorithm, thereby constantly improving the plasma-involving semiconductor process.

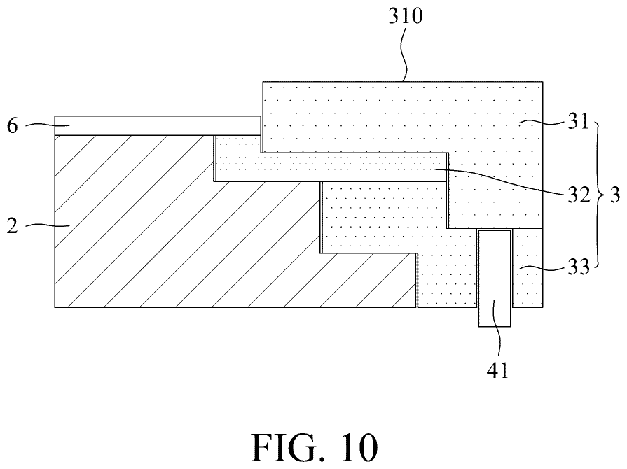

Referring to FIGS. 1, 2 and 10, a semiconductor processing apparatus is illustrated in accordance with a second embodiment. The second embodiment is similar to the first embodiment, and differs from the first embodiment in that each of the lift pins 41 of the second embodiment is adjacent to and disposed under a bottom of the first segment of the top ring 31, and extends through the lower segment of the bottom ring 33.

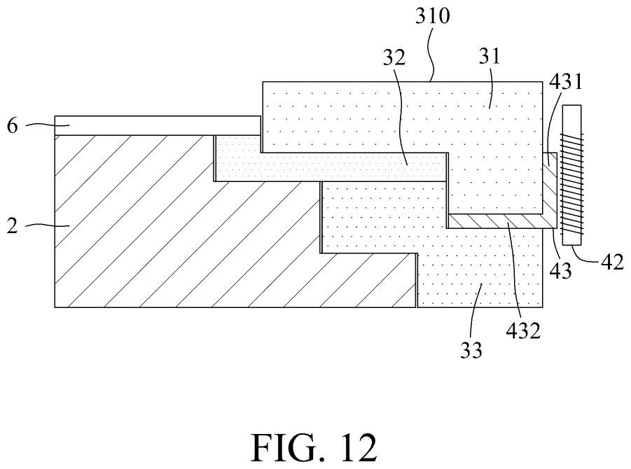

Referring to FIGS. 1, 11 and 12, a semiconductor processing apparatus is illustrated in accordance with a third embodiment. The third embodiment is similar to the first embodiment, and differs from the first embodiment in that the lifting mechanism 4 of the third embodiment uses magnetic force to lift up the parts 310 of the top ring 31. In the illustrative embodiment, the lifting mechanism 4 includes at least three magnetic lifting devices that respectively correspond in position to different parts 310 of the top ring 31. Each of the magnetic lifting devices includes an electromagnet component 42, and a magnetically-driven component 43 that is spaced apart from but adjacent to the electromagnet component 42. The electromagnet component 42 is electrically connected to the computerized module 10, and is disposed to generate magnetic force to drive vertical movement of the magnetically-driven component 43 when the electromagnet component 42 is activated by electricity. The magnetically-driven component 43 is disposed to move the corresponding part 310 of the top ring 31 upward when the magnetically-driven component 43 is driven into upward movement by the electromagnet component 42. The computerized module 10 controls activation of the electromagnet component 42. In practice, the computerized module 10 may control an intensity and/or orientation of a magnetic field generated by the electromagnet component 42 through a power supply (not shown) that provides electricity to the electromagnet component 42, so as to control movement of the magnetically-driven component 43 as desired. The use of the magnetic lifting devices may reduce particles created due to friction between mechanical components during the lifting of the top ring 31.

In the illustrative embodiment, the magnetically-driven component 43 is L-shaped in the sectional view, and includes a magnet portion 431 and a lift portion 432. The magnet portion 431 is disposed at an outer side of the corresponding part 310 of the top ring 31, and is disposed between the corresponding part 310 of the top ring 31 and the electromagnet component 42. The lift portion 432 is connected to the magnet portion 431, and is disposed under the corresponding part 310 of the top ring 31, so as to hold the corresponding part 310 of the top ring 31 from a bottom side. The lift portion 432 may be made using either the same material as or a different material from the magnet portion 431. In accordance with some embodiments, the lift portion 432 may be made using a non-magnetic material. In accordance with some embodiments, the magnet portion 431 and the lift portion 432 may be made in one piece, and the entire magnetically-driven component 43 may be made of a permanent magnet. The magnet portion 431 extends vertically, and the lift portion 432 extends inwardly from a lower end of the magnet portion 431 beneath the corresponding part 310 of the top ring 31. In accordance with some embodiments, the lift portion 432 may be omitted, in which case the magnet portion 431 is attached to an outer sidewall of the corresponding part 310 of the top ring 31, so that the corresponding part 310 of the top ring 31 is able to move vertically when the magnet portion 431 is driven into vertical movement by the electromagnet component 42.

In practice, finer adjustment of the plasma sheath profile can be achieved by increasing a number of the “adjustable” parts 310 of the top ring 31.

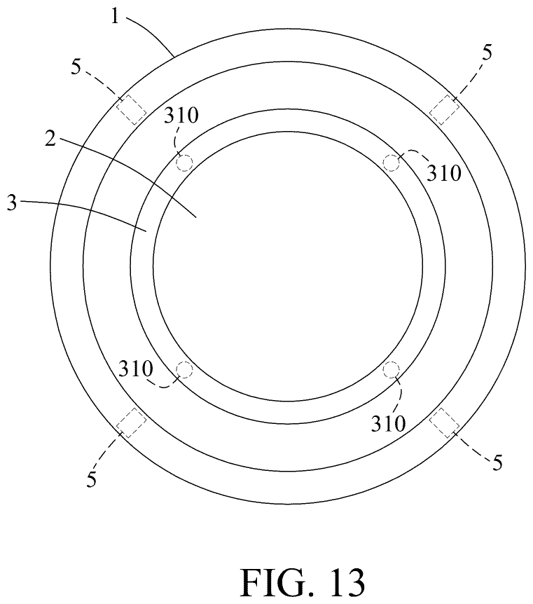

Referring to FIGS. 2, 11 and 13, a semiconductor processing apparatus is illustrated in accordance with a fourth embodiment. The fourth embodiment is similar to the first embodiment, and differs from the first embodiment in that the lifting mechanism 4 in the fourth embodiment includes four lift pins 41 or four magnetic lifting devices that correspond in position to four different parts 310 of the top ring 31. In the illustrative embodiment, the semiconductor processing apparatus also includes four monitor modules 5 for monitoring the height positions of the four parts 310 of the top ring 31, respectively.

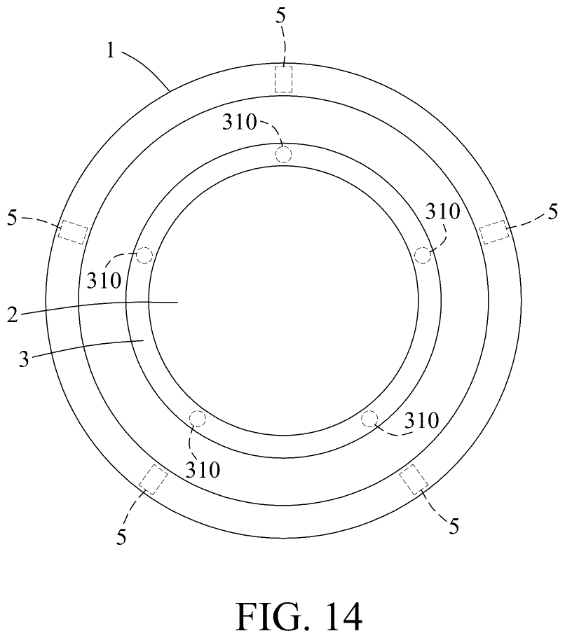

Referring to FIGS. 2, 11 and 14, a semiconductor processing apparatus is illustrated in accordance with a fifth embodiment. The fifth embodiment is similar to the first embodiment, and differs from the first embodiment in that the lifting mechanism 4 in the fifth embodiment includes five lift pins 41 or five magnetic lifting devices that correspond in position to five different parts 310 of the top ring 31. In the illustrative embodiment, the semiconductor processing apparatus also includes five monitor modules 5 for monitoring the height positions of the five parts 310 of the top ring 31, respectively.

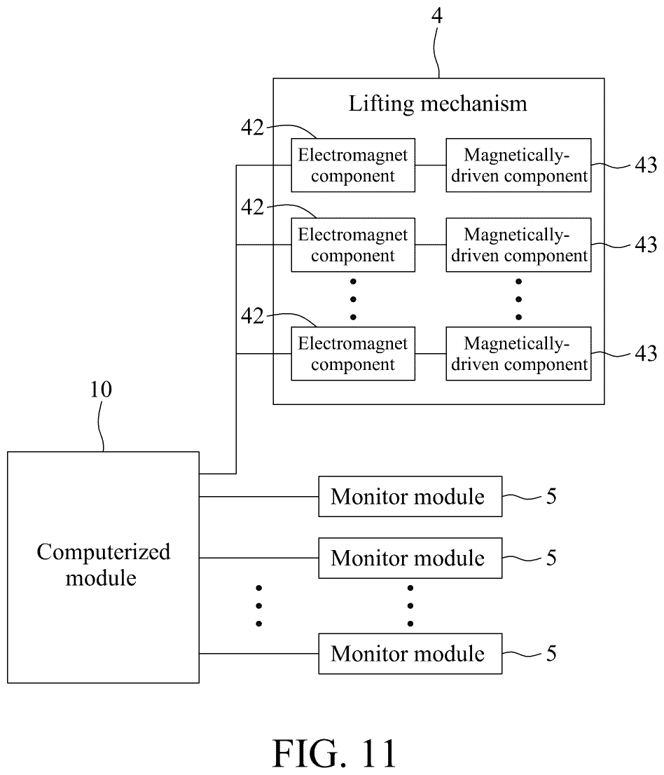

In each of FIGS. 1, 13 and 14, the parts 310 of the top ring 31 are arranged to be respectively located at corners of a regular polygon (e.g., an equilateral triangle, a square, or a regular pentagon), and so are the corresponding lift pins 41 (see FIG. 2) or magnetic lifting devices (see the combinations of the electromagnet component 42 and the magnetically-driven component 43 in FIG. 11), thereby achieving a good balance for supporting the top ring 31 even if the parts 310 of the top ring 31 are lifted to different height positions. However, this disclosure is not limited in this respect, as long as the top ring 31 can keep balance when the parts 310 of the top ring 31 are lifted to different height positions.

In accordance with some embodiments, a semiconductor processing apparatus is provided to include a wafer holder, a top ring surrounding the wafer holder when viewed from top, a lifting mechanism adjacent to the top ring, a monitor module, and a computerized module electrically connected to the lifting mechanism and the monitor module. The lifting mechanism is configured to lift a part of the top ring. The monitor module is disposed to monitor a current height position of the part of the top ring. The computerized module is configured to control the lifting mechanism to lift the part of the top ring from the current height position to a desired height position.

In accordance with some embodiments, the semiconductor processing apparatus includes a processing chamber in which the wafer holder is disposed. The monitor module is embedded in a chamber wall of the processing chamber.

In accordance with some embodiments, the monitor module includes at least two monitor devices located at different height positions to detect distances from the part of the top ring, respectively. The computerized module is configured to obtain the current height position of the part of the top ring based on the distances detected by the at least two monitor devices.

In accordance with some embodiments, the lifting mechanism includes at least three lift pins under the top ring, and one of the at least three lift pins is disposed under the part of the top ring. The computerized module is configured to control the lifting mechanism to move the one of the at least three lift pins upward so as to lift the part of the top ring.

In accordance with some embodiments, the lifting mechanism includes a magnetically-driven component disposed to move the part of the top ring upward when the magnetically-driven component is driven, and an electromagnet component electrically connected to the computerized module and disposed to generate a magnetic force to drive upward movement of the magnetically-driven component when the electromagnet component is activated by electricity. The computerized module is configured to control activation of the electromagnet component.

In accordance with some embodiments, the magnetically-driven component includes a magnet portion disposed at an outer side of the top ring and between the top ring and the electromagnet component.

In accordance with some embodiments, the magnetically-driven component further includes a lift portion connected to the magnet portion and disposed under the part of the top ring.

In accordance with some embodiments, the monitor module is configured to monitor an initial height position of the part of the top ring when the top ring is about to a semiconductor process that uses plasma. The computerized module treats the initial height position as the desired height position.

In accordance with some embodiments, the computerized module is disposed to receive a process recipe of a semiconductor process involving use of plasma, and is configured to calculate a plasma sheath profile for the semiconductor process based on the process recipe, and to obtain the desired height position based on the plasma sheath profile.

In accordance with some embodiments, a semiconductor processing apparatus is provided to include a wafer holder for holding a wafer to be processed, a top ring surrounding the wafer holder when viewed from top, a plasma generator configured to generate plasma for processing the wafer, a lifting mechanism adjacent to the top ring and configured to lift a part of the top ring, a monitor module disposed to monitor a state of the part of the top ring, and a computerized module electrically connected to the lifting mechanism and the monitor module. The computerized module is configured to, after the part of the top ring has been consumed by the plasma in a semiconductor process, determine a compensatory distance for the part of the top ring based on the state of the part of the top ring as monitored by the monitor module, and to control the lifting mechanism to lift the part of the top ring by the compensatory distance.

In accordance with some embodiments, the semiconductor processing apparatus includes a processing chamber in which the wafer holder is disposed. The monitor module is embedded in a chamber wall of the processing chamber.

In accordance with some embodiments, the chamber wall has at least two holes at different height positions, and the at least two holes correspond in position to the part of the top ring. The monitor module includes at least two monitor devices located respectively in the at least two holes of the chamber wall. Each of the at least two monitor devices is configured to detect a distance from the part of the top ring. The computerized module is configured to obtain the compensatory height based on the distances detected by the at least two monitor devices.

In accordance with some embodiments, the lifting mechanism includes at least three lift pins under the top ring, and one of the at least three lift pins is disposed under the part of the top ring. The computerized module is configured to control the lifting mechanism to move the one of the at least three lift pins upward so as to lift the part of the top ring.

In accordance with some embodiments, the lifting mechanism includes a magnetically-driven component disposed to move the part of the top ring upward when the magnetically-driven component is driven, and an electromagnet component electrically connected to the computerized module and disposed to generate a magnetic force to drive upward movement of the magnetically-driven component when the electromagnet component is activated by electricity. The computerized module is configured to control activation of the electromagnet component.

In accordance with some embodiments, the electromagnet component is disposed at an outer side of the top ring, and the magnetically-driven component includes a magnet portion disposed between the top ring and the electromagnet component.

In accordance with some embodiments, the magnetically-driven component further includes a lift portion extending from the magnet portion beneath the part of the top ring.

In accordance with some embodiments, the monitor module is configured to monitor an initial height position of the part of the top ring when the top ring is about to the semiconductor process that uses the plasma. The monitor module is configured to monitor a current height position of the part of the top ring after the part of the top ring has been consumed by the plasma in the semiconductor process. The computerized module is configured to obtain the compensatory distance based on the initial height position and the current height position of the part of the top ring.

In accordance with some embodiments, the computerized module is disposed to receive a process recipe of the semiconductor process involving use of the plasma, and is configured to calculate a plasma sheath profile for the semiconductor process based on the process recipe, and to obtain a desired height position of the part of the top ring based on the plasma sheath profile. The computerized module is configured to obtain the compensatory distance based on the state of the part of the top ring as monitored by the monitor module and the desired height position of the part of the top ring.

In accordance with some embodiments, a method is provided for performing a plasma-involving semiconductor process on a wafer. In one step, a monitor module is used to monitor a current height position of a part of a top ring of a semiconductor processing apparatus. The semiconductor processing apparatus includes a wafer holder, and the top ring surrounds the wafer holder when viewed from top. In one step, a computerized module is used to obtain a desired height position based on a desired plasma sheath. In one step, a lifting mechanism is used to lift the part of the top ring from the current height position to the desired height position. In one step, the semiconductor processing apparatus performs the plasma-involving semiconductor process on the wafer with the part of the top ring being lifted by the lifting mechanism.

In accordance with some embodiments, the desired plasma sheath profile is obtained based on a process recipe of the plasma-involving semiconductor process.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor processing apparatus, comprising:
a wafer holder;
a top ring surrounding the wafer holder when viewed from top;
a lifting mechanism adjacent to the top ring, and configured to lift a part of the top ring;
a monitor module disposed to monitor a current height position of the part of the top ring; and
a computerized module electrically connected to the lifting mechanism and the monitor module, and configured to control the lifting mechanism to lift the part of the top ring from the current height position to a desired height position.

2. The semiconductor processing apparatus according to claim 1, comprising a processing chamber in which the wafer holder is disposed,
wherein the monitor module is embedded in a chamber wall of the processing chamber.

3. The semiconductor processing apparatus according to claim 2, wherein the monitor module includes at least two monitor devices located at different height positions to detect distances from the part of the top ring, respectively; and
wherein the computerized module is configured to obtain the current height position of the part of the top ring based on the distances detected by the at least two monitor devices.

4. The semiconductor processing apparatus according to claim 1, wherein the lifting mechanism includes at least three lift pins under the top ring, and one of the at least three lift pins is disposed under the part of the top ring; and
wherein the computerized module is configured to control the lifting mechanism to move the one of the at least three lift pins upward so as to lift the part of the top ring.

5. The semiconductor processing apparatus according to claim 1, wherein the lifting mechanism includes a magnetically-driven component disposed to move the part of the top ring upward when the magnetically-driven component is driven, and an electromagnet component electrically connected to the computerized module and disposed to generate a magnetic force to drive upward movement of the magnetically-driven component when the electromagnet component is activated by electricity; and
wherein the computerized module is configured to control activation of the electromagnet component.

6. The semiconductor processing apparatus according to claim 5, wherein the magnetically-driven component includes a magnet portion disposed at an outer side of the top ring and between the top ring and the electromagnet component.

7. The semiconductor processing apparatus according to claim 6, wherein the magnetically-driven component further includes a lift portion connected to the magnet portion and disposed under the part of the top ring.

8. The semiconductor processing apparatus according to claim 1, wherein the monitor module is configured to monitor an initial height position of the part of the top ring when the top ring is about to a semiconductor process that uses plasma; and
wherein the computerized module treats the initial height position as the desired height position.

9. The semiconductor processing apparatus according to claim 1, wherein the computerized module is disposed to receive a process recipe of a semiconductor process involving use of plasma, and is configured to calculate a plasma sheath profile for the semiconductor process based on the process recipe, and to obtain the desired height position based on the plasma sheath profile.

10. A semiconductor processing apparatus, comprising:
a wafer holder for holding a wafer to be processed;
a top ring surrounding the wafer holder when viewed from top;
a plasma generator configured to generate plasma for processing the wafer;
a lifting mechanism adjacent to the top ring, and configured to lift a part of the top ring;
a monitor module disposed to monitor a state of the part of the top ring; and
a computerized module electrically connected to the lifting mechanism and the monitor module;
wherein the computerized module is configured to, after the part of the top ring has been consumed by the plasma in a semiconductor process, determine a compensatory distance for the part of the top ring based on the state of the part of the top ring as monitored by the monitor module, and to control the lifting mechanism to lift the part of the top ring by the compensatory distance.

11. The semiconductor processing apparatus according to claim 10, comprising a processing chamber in which the wafer holder is disposed,
wherein the monitor module is embedded in a chamber wall of the processing chamber.

12. The semiconductor processing apparatus according to claim 11, wherein the chamber wall has at least two holes at different height positions, and the at least two holes correspond in position to the part of the top ring;
wherein the monitor module includes at least two monitor devices located respectively in the at least two holes of the chamber wall;
wherein each of the at least two monitor devices is configured to detect a distance from the part of the top ring; and
wherein the computerized module is configured to obtain the compensatory height based on the distances detected by the at least two monitor devices.

13. The semiconductor processing apparatus according to claim 10, wherein the lifting mechanism includes at least three lift pins under the top ring, and one of the at least three lift pins is disposed under the part of the top ring; and
wherein the computerized module is configured to control the lifting mechanism to move the one of the at least three lift pins upward so as to lift the part of the top ring.

14. The semiconductor processing apparatus according to claim 10, wherein the lifting mechanism includes a magnetically-driven component disposed to move the part of the top ring upward when the magnetically-driven component is driven, and an electromagnet component electrically connected to the computerized module and disposed to generate a magnetic force to drive upward movement of the magnetically-driven component when the electromagnet component is activated by electricity; and
wherein the computerized module is configured to control activation of the electromagnet component.

15. The semiconductor processing apparatus according to claim 14, wherein the electromagnet component is disposed at an outer side of the top ring, and the magnetically-driven component includes a magnet portion disposed between the top ring and the electromagnet component.

16. The semiconductor processing apparatus according to claim 15, wherein the magnetically-driven component further includes a lift portion extending from the magnet portion beneath the part of the top ring.

17. The semiconductor processing apparatus according to claim 10, wherein the monitor module is configured to monitor an initial height position of the part of the top ring when the top ring is about to the semiconductor process that uses the plasma;
wherein the monitor module is configured to monitor a current height position of the part of the top ring after the part of the top ring has been consumed by the plasma in the semiconductor process; and
wherein the computerized module is configured to obtain the compensatory distance based on the initial height position and the current height position of the part of the top ring.

18. The semiconductor processing apparatus according to claim 10, wherein the computerized module is disposed to receive a process recipe of the semiconductor process involving use of the plasma, and is configured to calculate a plasma sheath profile for the semiconductor process based on the process recipe, and to obtain a desired height position of the part of the top ring based on the plasma sheath profile; and
wherein the computerized module is configured to obtain the compensatory distance based on the state of the part of the top ring as monitored by the monitor module and the desired height position of the part of the top ring.

19. A method for performing a plasma-involving semiconductor process on a wafer, comprising:
by a monitor module, monitoring a current height position of a part of a top ring of a semiconductor processing apparatus, wherein the semiconductor processing apparatus includes a wafer holder, and the top ring surrounds the wafer holder when viewed from top;
by a computerized module, obtaining a desired height position based on a desired plasma sheath;
by a lifting mechanism, lifting the part of the top ring from the current height position to the desired height position; and
by the semiconductor processing apparatus, performing the plasma-involving semiconductor process on the wafer with the part of the top ring being lifted by the lifting mechanism.

20. The method according to claim 19. wherein the desired plasma sheath profile is obtained based on a process recipe of the plasma-involving semiconductor process.
